(19) United States
(12) Patent Application Publication
(10) Pub. No.: US 2014/0118902 A1
(43) Pub. Date: May 1, 2014

(54) DISPLAY DEVICE AND METHOD FOR MANUFACTURING THE SAME

(71) Applicant: SAMSUNG DISPLAY CO., LTD, Yongin-city (KR)

(72) Inventor: Dong Cheol Kim, Yongin-si (KR)

(73) Assignee: SAMSUNG DISPLAY CO., LTD, Yongin-city (KR)

(21) Appl. No.: 13/950,081

(22) Filed: Jul. 24, 2013

(30) Foreign Application Priority Data
Oct. 25, 2012 (KR) 10-2012-0119213

(51) Int. Cl. H05K 7/02

(52) U.S. Cl. CPC H05K 7/02
USPC 361/679.01; 156/273.3

(57) ABSTRACT

A display device includes a display panel including a display region and a non-display region; a window located on one surface of the display panel; and an adhesive layer located between the display panel and the window, wherein a modulus of elasticity of the adhesive layer located on the non-display region is greater than a module of elasticity of the adhesive layer located on the display region.

### CROSS-REFERENCE TO RELATED APPLICATION

This application claims priority to and the benefit of Korean Patent Application No. 10-2012-0119213 filed on Oct. 25, 2012 in the Korean Intellectual Property Office, the disclosure of which is incorporated herein by reference in its entirety.

### BACKGROUND

1. Field

The present invention relates to a display device and a method for manufacturing the same.

2. Description of the Related Art

A display device displays an image and examples thereof include a liquid crystal display device, a plasma display device, and an organic light emitting display device.

Among display devices, the liquid crystal display device displays a desired image by placing a liquid crystal layer between two transparent substrates and adjusting a light transmission rate for each pixel according to driving of the liquid crystal layer. At an initial stage, the liquid crystal layer of the liquid crystal display device is oriented in a direction perpendicular to or parallel to a substrate to then be interposed between two substrates. Transparent electrodes are arranged on the substrates. When an electric field is created between the electrodes for each pixel, orientation of liquid crystal molecules forming the liquid crystal layer may change. In absence of an electric field created between the transparent electrodes, the liquid crystal molecules tend to restore into initial orientation state.

When an external force is applied to a conventional liquid crystal display device due to a user's touch, the liquid crystal molecules arranged in the display panel of the liquid crystal display device are oriented according to the direction in which the external force is applied even without the electric field created, undesired phenomena may occur, including a smearing phenomenon in which smear is formed at a portion to which an external force is applied, a bruising phenomenon in which a restoration speed of liquid crystal molecules is reduced toward initial orientation, or a pooling phenomenon in which liquid crystal molecules continuously slosh in the direction in which the external force is applied. The smearing, bruising or pooling phenomenon may occur in a display region of the display panel, resulting in deterioration of display quality in the display device.

In order to avoid the smearing, bruising or pooling phenomenon, a window is located on the display panel of the display device, a double-sided tape is applied between the edge of the display panel and the window, thereby forming an air layer in a region surrounded by the display panel, the window and the double-sided tape.

In this case, however, the light emitted from the display device may be subjected to interfacial reflection in the air layer, resulting in luminance deterioration of the display device.

### SUMMARY

Accordingly, the present invention provides a display device, which can prevent a smearing phenomenon, a bruising phenomenon or a polling phenomenon by reducing an external force applied to a display region of a display panel without luminance deterioration of the display device even when the external force is applied to the display panel of the display device.

The present invention also provides a method for manufacturing a display device, which can prevent a smearing phenomenon, a bruising phenomenon or a polling phenomenon by reducing an external force applied to a display region of a display panel without luminance deterioration of the display device even when the external force is applied to the display panel of the display device.

The above and other objects of the present invention will be described in or be apparent from the following description of the preferred embodiments.

According to an aspect of the present invention, there is provided a display device including a display panel including a display region and a non-display region, a window located on one surface of the display panel, and an adhesive layer disposed between the display panel and the window, wherein a modulus of elasticity of the adhesive layer located on the non-display region is greater than that of the adhesive layer located on the display region.

According to another aspect of the present invention, there is provided a display device including a display panel including a display region and a non-display region, a window located on one surface of the display panel, and a first adhesive layer and a second adhesive layer disposed between the display panel and the window, wherein the second adhesive layer is located on at least a portion on the non-display region, a modulus of elasticity of the second adhesive layer is greater than that of the first adhesive layer.

According to still another aspect of the present invention, there is provided a display device including a display panel including a display region and a non-display region, a window located on one surface of the display panel, and an adhesive layer disposed between the display panel and the window, wherein the adhesive layer located on the non-display region includes a photocurable material.

According to a further aspect of the present invention, there is provided a method for manufacturing a display device, the method including applying an adhesive layer including a photocurable material on a display panel, differentially irradiating light into the display panel; and attaching a window onto the adhesive layer.

Embodiments of the present invention provide at least the following effects.

That is to say, a smearing phenomenon, a bruising phenomenon or a polling phenomenon can be prevented by reducing an external force applied to a display region of a display panel without luminance deterioration of the display device even when the external force is applied to the display panel of the display device.

### BRIEF DESCRIPTION OF THE DRAWINGS

The above and other features and advantages of the present invention will become more apparent by describing in detail preferred embodiments thereof with reference to the attached drawings in which:

FIG. 1 is an exploded perspective view of a display device according to an embodiment of the present invention;

FIG. 2 is a perspective view illustrating a display panel, a window, and an adhesive layer of the display device shown in FIG. 1;

FIG. 3 is a cross-sectional view taken along the line A-A, illustrating the display panel, the window, and the adhesive layer shown in FIG. 2;

FIG. 4 is a cross-sectional view illustrating a display panel, a window, and an adhesive layer of a display device according to another embodiment of the present invention;

FIG. 5 is a cross-sectional view illustrating a display panel, a window, and an adhesive layer of a display device according to still another embodiment of the present invention;

FIGS. 6 to 8 are cross-sectional views illustrating a display panel, a window, first adhesive layers and second adhesive layers of a display device according to still another embodiment of the present invention;

FIGS. 9 and 10 are plan views illustrating a display panel, a window, first adhesive layers and second adhesive layers of a display device according to still another embodiment of the present invention; and

FIGS. 11 to 13 are cross-sectional views illustrating a method for manufacturing a display device according to an embodiment of the present invention.

### DETAILED DESCRIPTION

Features of the present invention and methods of accomplishing the same may be understood more readily by reference to the following detailed description of embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Thus, in some embodiments, well-known structures and devices are not shown in order not to obscure the description of the invention with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Various example embodiments will be described more fully hereinafter with reference to the accompanying drawings, in which some example embodiments are shown.

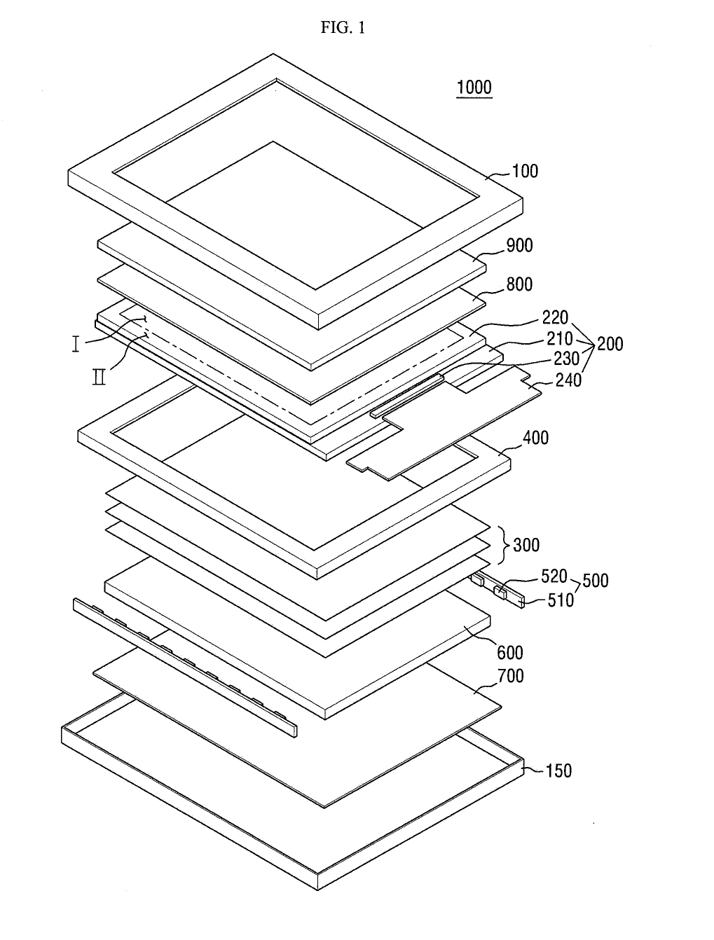

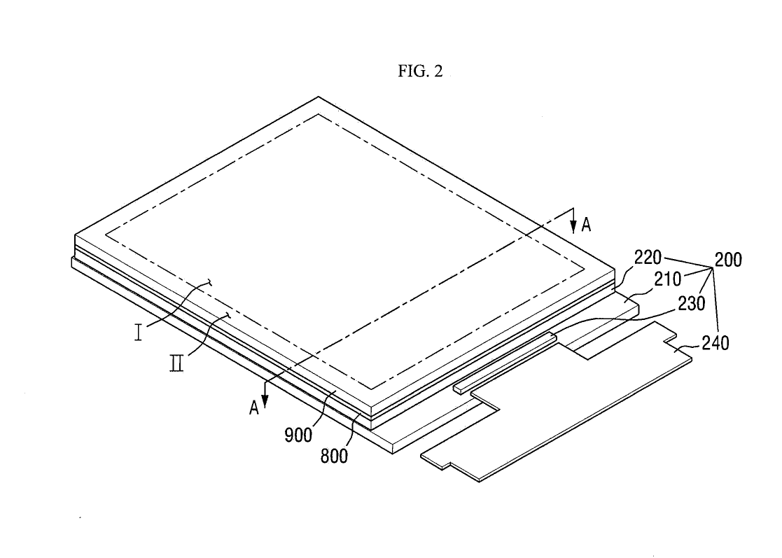

FIG. 1 is an exploded perspective view of a display device (1000) according to an embodiment of the present invention and FIG. 2 is a perspective view illustrating a display panel (200), a window (900), and an adhesive layer (800) of the display device (1000) shown in FIG. 1.

Referring to FIGS. 1 and 2, the display device 1000 includes a display panel 200, a window 900, and an adhesive layer 800. In addition, the display device 1000 may further include a light source assembly, a top chassis 100, and a bottom chassis 150.

The display panel 200 is a panel for displaying an image and may include a liquid crystal display (LCD) panel, an electrophoretic display panel, an organic light emitting diode (OLED) panel, a light emitting diode (LED) panel, an inorganic electroluminescent display panel, a field emission display (FED) panel, a surface-conduction electron-emitter display (SED) panel, a plasma display panel (PDP), and a cathode ray tube (CRT) display panel 200. The following description will be made with regard to a liquid crystal display device as the display device 1000 according to an embodiment of the present invention, but the display device 1000 and the display panel 200 are not limited to those illustrated herein. A variety of types of display devices and display panels may be used as the display device 1000 and the display panel 200.

The display panel 200 includes a display region and a non-display region. In addition, the display panel 200 may include a first substrate 210, a second substrate 220 facing the first substrate 210, a liquid crystal layer, and a driver 230 and a flexible circuit board 240 attached onto the first substrate 210.

The display region of the display panel 200 may mean a region on which an image is displayed, and the non-display region of the display panel 200 may mean a region on which an image is not displayed. In a plan view of the display panel 200, as will be described later, the display region may be centrally positioned in an overlapping region of the first substrate 210 and the second substrate 220, and the non-display region may be positioned in an edge portion of the overlapping region of the first substrate 210 and the second substrate 220. In addition, the display region may be a region in which the display panel 200 and the top chassis 100 do not overlap each other, and the non-display region may be a region in which the display panel 200 and the top chassis 100 overlap each other. In addition, in the plan view of the display panel 200, the display region has a shape similar to the second substrate 220 but has a smaller area than the second substrate 220. In addition, in the plan view of the display panel 200, boundary lines of the display region and the non-display region may be parallel to sides of the second substrate 220 facing the boundary lines. In addition, the shape formed by the boundary lines of the display region and the non-display region may be a rectangular shape. In FIGS. 1 and 2, the shape formed by the boundary lines of the display region and the non-display region is a rectangular shape, but not limited thereto. However, the shape formed by the boundary lines of the display region and the non-display region may be a circular or polygonal shape according to the shape of the display panel 200.

At least a portion of the first substrate 210 may overlap the second substrate 220. As described above in the plan view of the display panel 200, the central portion of the overlapping region of the first substrate 210 and the second substrate 220 may be a display region, and the edge portion of the overlapping region of the first substrate 210 and the second substrate 220 may be a non-display region. The driver 230 and the flexible circuit board 240 may be attached onto a region in which the first substrate 210 and the second substrate 220 do not overlap each other.

The second substrate 220 may be oriented to face the first substrate 210. A liquid crystal layer may be located between the first substrate 210 and the second substrate 220. A sealing member such as a sealant may be located between the first substrate 210 and the second substrate 220 along edge portions of the first substrate 210 and the second substrate 220 and adheres and seals the substrate 210 and the second substrate 220 to each other.

The first substrate 210 and the second substrate 220 may have rectangular parallelepiped shapes. For the sake of convenient explanation, FIGS. 1 and 2 show that the first substrate 210 and the second substrate 220 have rectangular parallelepiped shapes, but aspects of the present invention are not limited thereto. The first substrate 210 and the second substrate 220 may be manufactured in various shapes according to the shape of the display panel 200.

The driver 230 may apply various signals, including driving signals required to display an image on a display region. The flexible circuit board 240 may output various signals to the driver 230.

The window 900 may be positioned on one surface of the display panel 200. The window 900 prevents a shock from being directly applied to the display panel 200 and prevents the display panel 200 from being contaminated by foreign matter.

The window 900 may be formed of glass, plastic or a combination thereof. In addition, the window 900 may be transparent. The window 900 may be mechanically strong enough to sufficiently absorb the shock applied to the display panel 200. In other words, the window 900 may be formed of reinforced glass. In addition, the window 900 may have a rectangular parallelepiped shape. FIGS. 1 and 2 show that the window 900 has a rectangular parallelepiped shapes, but aspects of the present invention are not limited thereto. The window 900 may be manufactured in various shapes according to the shape of the display panel 200.

One surface of the window 900 facing the display panel 200 may be parallel with one surface of the display panel 200. In addition, at least a portion of the window 900 may overlap the second substrate 220 of the display panel 200. For the sake of convenient explanation, FIGS. 1 and 2 show that the window 900 completely overlaps the second substrate 220, but aspects of the present invention are not limited thereto. Only a portion of the window 900 may overlap the second substrate 220 of the display panel 200 but may completely overlap the first substrate 210, rather than the second substrate 220.

The adhesive layer 800 is located between the display panel 200 and the window 900. The display panel 200 and the window 900 may be adhered and fixed to each other by means of the adhesive layer 800. In addition, when an external force is applied to the display panel 200 of the liquid crystal display device 1000, the adhesive layer 800 disperses the external force, thereby preventing a bruising or pooling phenomenon from occurring to the display region of the display panel 200, which will later be described.

The adhesive layer 800 may include at least one of a thermally curable adhesive, a catalyst-added adhesive, a humidity curing adhesive, an anaerobic forming adhesive, a hot melt adhesive, a dehumidifying adhesive, an optically clear adhesive, and a pressure sensitive adhesive. In an exemplary embodiment, the adhesive layer 800 may include at least one of an optically clear adhesive (OCA) and a pressure sensitive adhesive (PSA). In one embodiment, the optically clear adhesive and the pressure sensitive adhesive may be transparent and semi-solid. In general, since a semi-solid material can be easily fixed in its shape, the optically clear adhesive and the pressure sensitive adhesive in semi-solid phases can be handled more easily than a resin in a liquid phase.

At least a portion of the adhesive layer 800 may overlap the second substrate 220 of the display panel 200 or the window 900. FIGS. 1 and 2 show that the adhesive layer 800 completely overlaps the second substrate 220 of the display panel 200 and the window 900, but aspects of the present invention are not limited thereto. However, only a portion of the adhesive layer 800 may overlap the window 900. In addition, the adhesive layer 800 may overlap a portion of the second substrate 220.

A refractive index of the adhesive layer 800 may be similar to that of the second substrate 220 of the display panel 200 and the window 900 directly contacting the adhesive layer 800 or may be equal to that of one of the second substrate 220 of the display panel 200 and the window 900. In an exemplary embodiment, the refractive index of the adhesive layer 800 may be a median value of the refractive index of the second substrate 220 and the refractive index of the window 900. The refractive index of the adhesive layer 800 may be adjusted to be a median value of the refractive index of the second substrate 220 and the refractive index of the window 900 by adding a transparent material, such as a silicon oxide, to the adhesive layer 800. Therefore, since the light emitted from the display device 1000 is barely refracted when it sequentially passes through the second substrate 220, the adhesive layer 800, and the window 900, luminance deterioration of the display device 1000 can be prevented.

A light source assembly may be located on the other surface of the display panel 200. The light source assembly may include a light source unit 500 including a light source 520 for emitting light and a circuit board 510 on which the light source 520 is disposed, a light guide plate 600 that guides the light emitted from the light source unit 500, a reflective sheet 700 located below the light guide plate 600 and changing the path of the light traveling to a lower portion of the light guide plate 600, at least one optical sheet 300 positioned above the light guide plate 600 and changing optical properties of the emitted light, and a mold frame 400 accommodating these components.

Here, the mold frame 400 makes contact with an edge portion of the other surface of the display panel 200 and supports and fixes the display panel 200. In an exemplary embodiment, the edge portion of the other surface of the display panel 200 may be a non-display region of the display panel 200. In other words, at least a portion of the mold frame 400 may overlap the non-display region of the display panel 200.

FIG. 1 shows that the display device 1000 includes an edge-type light source assembly having the light source 520 positioned at a side as a light source assembly, but aspects of the present invention are not limited thereto. However, a direct-type light source assembly having the light source 520 positioned at a lower portion may also be used in the display device 1000.

The top chassis 100 may cover the edge portion of the display panel 200 and may surround the display panel 200 and side surfaces of the light source assembly. The bottom chassis 150 may accommodate the optical sheet 300, the light guide plate 600, the light source unit 500, and the reflective sheet 700. The top chassis 100 and the bottom chassis 150 may be made of a conductive material, e.g., a metal.

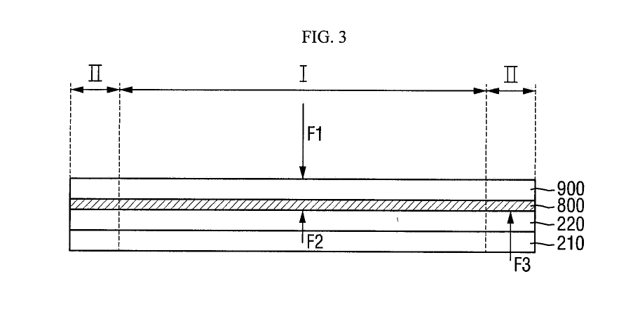

Hereinafter, the display panel 200, the window 900, the adhesive layer 800 and dispersion of the external force applied to the display panel 200 will be described in more detail with reference to FIG. 3, which is a cross-sectional view taken along the line A-A, illustrating the display panel 200, the window 900, and the adhesive layer 800 of the display device 1000 shown in FIG. 2.

Referring to FIG. 3, in the display device 1000 according to the embodiment of the present invention, the first substrate 210, the second substrate 220, the adhesive layer 800 and the window 900 may be sequentially stacked. FIG. 3 shows that the first substrate 210, the second substrate 220, the window 900 and the adhesive layer 800 completely overlap each other, but aspects of the present invention are not limited thereto. In order to facilitate stacking, the first substrate 210, the second substrate 220, the adhesive layer 800 and the window 900 may be stacked in a pyramidal configuration. In order to more firmly protect the first substrate 210 and the second substrate 220, the window 900 may further protrude towards side portions of the first substrate 210, the second substrate 220 and the adhesive layer 800.

As described above, the display region may be a central portion of the display panel 200, that is, a central portion of the first substrate 210 and the second substrate 220, and the non-display regions may be edge portions of the first substrate 210 and the second substrate 220. The non-display regions may be symmetrical to each other in view of the display region. The adhesive layer 800 and the window 900 corresponding to the display region and the non-display region may be positioned on the display region and the non-display region.

In the display device 1000 according to the embodiment of the present invention, a modulus of elasticity of the adhesive layer 800 located on the non-display region is greater than that of the adhesive layer 800 located on the display region.

In one embodiment, the adhesive layer 800 is divided into an adhesive layer 800 located on the display region and an adhesive layer 800 located on the non-display region, but aspects of the present invention are not limited thereto. Unlike the term defined in commonly used dictionaries, the adhesive layer 800 located on the display region may mean a portion of the adhesive layer 800 located on the non-display region adjacent to the display region, and the adhesive layer 800 located on the non-display region may mean a portion of the adhesive layer 800 located on the display region adjacent to the non-display region.

The modulus of elasticity is an indicator of an elastic property of a given material and may mean a ratio of stress to deformation. In one embodiment, the stress may mean a resistance required to maintain the shape of an object to withstand an external force when the external force is applied to the object and may also be referred to as elastic force. The deformation may mean a change in the shape of an object. For example, assuming that the same extent of deformation is applied to objects A and B, if the elastic force of the object A is greater than that of the object B, a modulus of elasticity of the object A is greater than that of the object B. In one embodiment, the object A may correspond to the adhesive layer 800 located on the non-display region and the object B may mean the adhesive layer 800 located on the display region.

In general, when an object is deformed within an elasticity limit, the magnitude of the elastic force is proportional to the extent of deformation and the elastic force acts in a direction opposite to a direction in which the object is deformed. In an exemplary embodiment, since the elasticity limit of the adhesive layer 800 is sufficiently large, it may not be necessarily taken into consideration.

Referring to FIG. 3, when an external force is applied from an upper portion of the window 900 toward the display panel 200, the adhesive layer 800 may be deformed. In an exemplary embodiment, the external force may be applied to the display panel 200 in a direction perpendicular to one surface of the window 900. Here, a thickness of the adhesive layer 800 may be reduced. Since the adhesive layer 800 may directly contact the display panel 200 and the window 900, the thickness of the adhesive layer 800 may mean a shortest distance between the display panel 200 and the window 900. In addition, since the one surface of the window 900 facing the display panel 200 may be parallel with one surface of the display panel 200, the adhesive layer 800 may have a uniform thickness throughout the display region and the non-display region and the window 900 may be formed of rigid glass, plastic or a combination thereof, the thickness of the adhesive layer 800 can be reduced uniformly when the external force is applied to the adhesive layer 800. That is to say, the adhesive layer 800 located on the display region and the adhesive layer 800 located on the non-display region may undergo the same thickness reduction.

Since the adhesive layer 800 has a reduced thickness, that is, the adhesive layer 800 is deformed, due to an external force applied from the upper portion of the window 900 toward the display panel 200, an elastic force is applied to the adhesive layer 800 in a direction opposite to a direction in which the external force is applied. Although not shown in FIG. 3, since the display panel 200 and the mold frame 400 positioned below the adhesive layer 800 may also be deformed, an elastic force may also be generated in the display panel 200 and the mold frame 400.

The elastic force generated in the adhesive layer 800 may include an elastic force from the adhesive layer 800 located on the display region and an elastic force from the adhesive layer 800 located on the non-display region. The adhesive layer 800 located on the display region and the adhesive layer 800 located on the non-display region undergo the same thickness reduction due to the external force applied, and a modulus of elasticity of the adhesive layer 800 located on the non-display region is greater than that of the adhesive layer 800 located on the display region, the elastic force from the adhesive layer 800 located on the non-display region may be larger than that from the adhesive layer 800 located on the display region, which means that a larger external force is applied to the non-display region of the display panel 200 than to the display region of the display panel 200.

In another exemplary embodiment, the modulus of elasticity of the adhesive layer 800 may gradually increase from inside to outside of the display panel 200. For example, the modulus of elasticity of the adhesive layer 800 may uniformly increase from inside to outside of the display panel 200. In addition, the modulus of elasticity of the adhesive layer 800 may exponentially increase from inside to outside of the display panel 200. In one embodiment, the inside of the display panel 200 may mean a central portion in a plan view of the display panel 200, and the outside of the display panel 200 may mean an edge portion in the plan view of the display panel 200.

In still another exemplary embodiment, the modulus of elasticity of the adhesive layer 800 is constant throughout the display region. In other words, the modulus of elasticity of the adhesive layer 800 may be constant from the inside to the outside of the display panel 200 and may increase at an interface between the display region and the non-display region sharply or with a constant slope.

In still another exemplary embodiment, the adhesive layer 800 located on the non-display region of the display panel 200 may include a photocurable material. The photocurable material may mean an organic material that is crosslinked or cured by light such as ultraviolet (UV) ray or electron beam (EB). In an exemplary embodiment, the photocurable material may be a UV curable material cured by UV ray and including oligomer, monomer, a photo initiator and other additives. The photocurable material may be transparent.

An amount of the photocurable material may increase from inside to outside of the display panel 200. In addition, the adhesive layer 800 located on the display region may also include a photocurable material. In one embodiment, an amount of the photocurable material on the non-display region may be larger than that of the photocurable material on the display region.

As described above, if the adhesive layer 800 including a photocurable material is at least partially cured by the light corresponding to the photocurable material, the cured adhesive layer 800 increasingly tends to maintain its original shape. Therefore, the modulus of elasticity of the adhesive layer 800 may increase.

Like in the display device 1000 according to the embodiment of the present invention, if the modulus of elasticity of the adhesive layer 800 located on the non-display region is made greater than that of the adhesive layer 800 located on the display region, an external force applied to the display region of the display panel 200 is reduced even when the external force is applied to the display panel 200 of the display device 1000, thereby preventing a smearing, bruising or pooling phenomenon from occurring in the display region of the display panel 200. Accordingly, high display quality in the display region of the display panel 200 can be achieved.

In addition, as described above, an air layer may not exist between the display panel 200 and the window 900 but the adhesive layer 800 may exist therebetween, and a refractive index of the adhesive layer 800 may be similar to that of the second substrate 220 of the display panel 200 or the window 900 or may be equal to one of the refractive index of the second substrate 220 or the window 900, the light emitted from the display device 1000 is minimally refracted when it sequentially passes through the second substrate 220, the adhesive layer 800, and the window 900, luminance deterioration of the display device 1000 can be prevented.

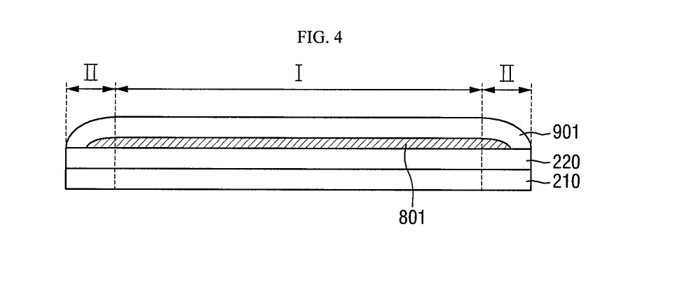

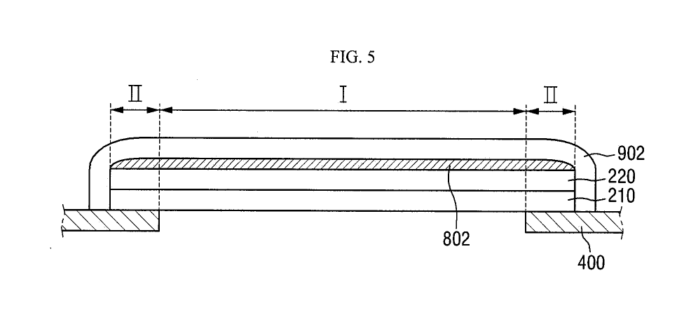

FIG. 4 is a cross-sectional view illustrating a display panel (200), a window (901), and an adhesive layer (801) of a display device according to another embodiment of the present invention. FIG. 5 is a cross-sectional view illustrating a display panel (200), a window (902), and an adhesive layer (802) of a display device according to still another embodiment of the present invention. In FIGS. 4 and 5, for the sake of convenient explanation, substantially the same elements as those shown in FIGS. 1 to 3 are denoted by the same reference numerals, and repeated descriptions thereof will be omitted.

Referring to FIG. 4, the window 901 of the display device according to another embodiment of the present invention is bent on a non-display region and may contact the display panel 200. The adhesive layer 801 may be positioned in a region surrounded by the window 901 and the display panel 200. In one embodiment, a contact portion of the window 901 and the display panel 200 may be part of a non-display region of the display panel 200. In addition, the window 901 may be bent as illustrated. FIG. 4 shows that the contact portion of the window 901 and the display panel 200 is part of the non-display region and the window 901 is bent while drawing a curved line as illustrated, but aspects of the present invention are not limited thereto. However, the contact portion of the window 901 and the display panel 200 may be the whole of the non-display region and the window 901 may be bent while drawing a curved line.

Referring to FIG. 5, the window 902 of the display device according to still another embodiment of the present invention is bent on a non-display region and may contact the mold frame 400. The adhesive layer 802 may be positioned in a region surrounded by the window 902 and the display panel 200. In one embodiment, the window 902 may contact a side surface of the display panel 200. FIG. 5 shows that the window 902 is bent while drawing a curved line, but aspects of the present invention are not limited. The window 902 may be bent while being positioned at right angle.

According to another and still another embodiments of the present invention, ends of the rigid windows 901 and 902 are made to contact with the non-display region of the display panel 200 or the mold frame 400, thereby transmitting most of an external force to the non-display region of the display panel 200 or the mold frame 400 when the external force is applied to the display panel 200 above the windows 901 and 902.

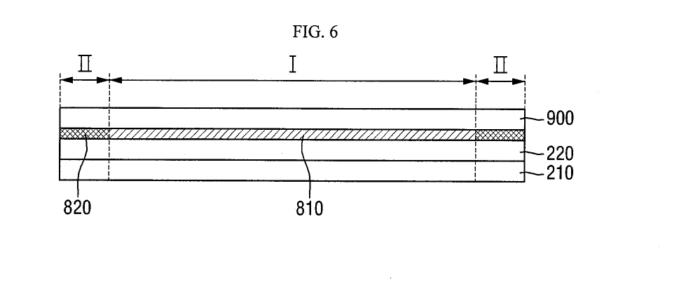

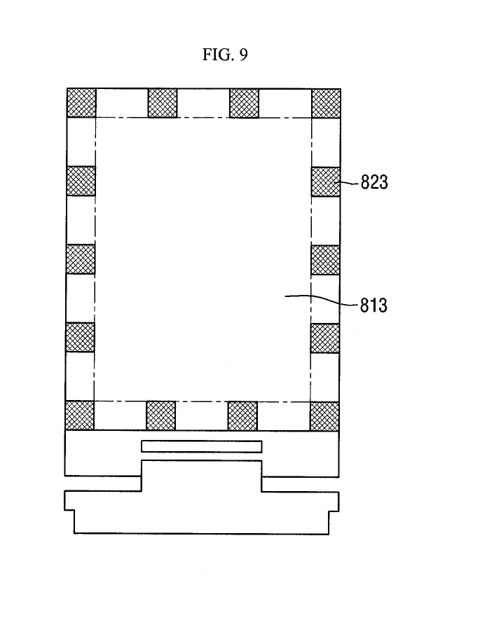

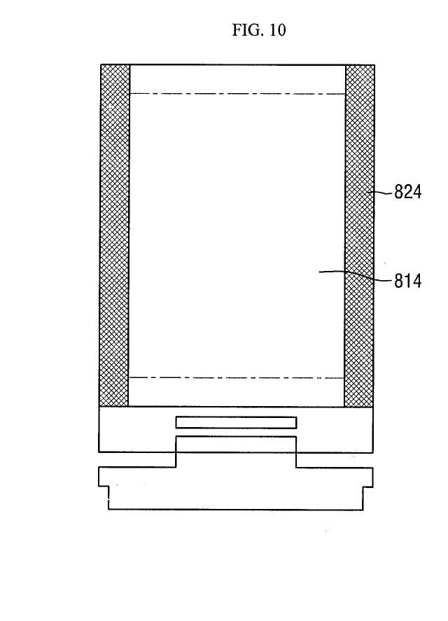

FIGS. 6 to 8 are cross-sectional views illustrating a display panel (200), a window (900), first adhesive layers (810, 811, 812) and second adhesive layers (820, 821, 822) of a display device according to still another embodiment of the present invention. FIGS. 9 and 10 are plan views illustrating a display panel (200), a window (900), first adhesive layers (813, 814) and second adhesive layers (823, 824) of a display device according to still another embodiment of the present invention. In FIGS. 6 to 8, for the sake of convenient explanation, substantially the same elements as those shown in FIGS. 1 to 3 are denoted by the same reference numerals, and repeated descriptions thereof will be omitted.

Referring to FIG. 6, the display device according to another embodiment of the present invention includes a first adhesive layer 810 and a second adhesive layer 820 positioned between the display panel 200 and the window 901. The first adhesive layer 810 and the second adhesive layer 820 may fill a portion between the display panel 200 and the window 900 without pores. The first adhesive layer 810 and the second adhesive layer 820 may be made of different materials. In an exemplary embodiment, the first adhesive layer 810 and the second adhesive layer 820 may be made of different optically clear adhesives.

The second adhesive layer 820 is positioned on at least a portion on a non-display region of the display panel 200, and a modulus of elasticity of the second adhesive layer 820 is greater than that of the first adhesive layer 810. In addition, the modulus of elasticity of the second adhesive layer 820 may gradually increase from inside to outside of the display panel 200. In addition, at least a portion of the first adhesive layer 810 may be positioned on a display region of the display panel 200 and the modulus of elasticity of the first adhesive layer 810 may be constant throughout the display region. In addition, the first adhesive layer 810 and the second adhesive layer 820 may be positioned on the same plane.

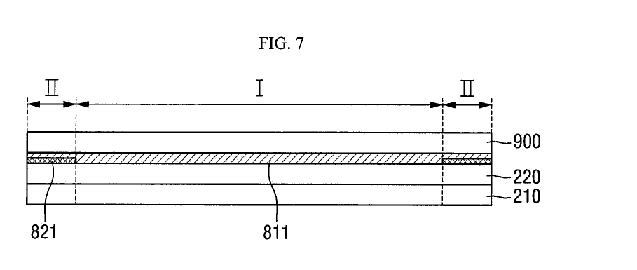

Referring to FIG. 7, at least a portion of the first adhesive layer 811 may overlap the second adhesive layer 821. In an exemplary embodiment, the display region of the display panel 200 may be formed of a single layer of the first adhesive layer 811, while the non-display region may be formed of dual layers of the first adhesive layer 811 and the second adhesive layer 821. Here, the dual layers may be formed such that the second adhesive layer 821 makes direct contact with the second substrate 220 of the display panel 200 and the first adhesive layer 811 makes direct contact with the window 900. In an exemplary embodiment, the dual layers may be formed by forming the second adhesive layer 821 on the non-display region of the display panel 200, and forming the first adhesive layer 811 on the display region and the non-display region of the display panel 200. As described above, the dual layers of the first adhesive layer 811 and the second adhesive layer 821 located on the non-display region may have a greater modulus of elasticity than the single layer of the first adhesive layer 811 located on the display region.

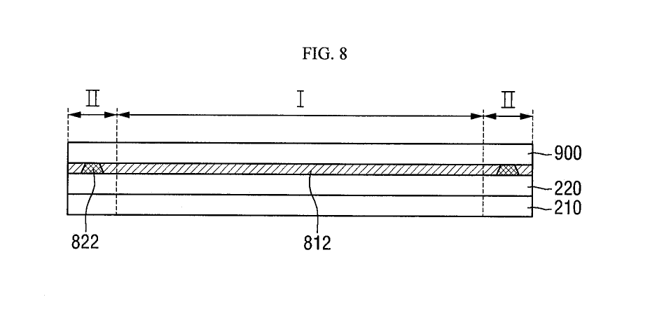

Referring to FIG. 8, the second adhesive layer 822 may be formed on a portion of the non-display region of the display panel 200 in an island shape. In one embodiment, the first adhesive layer 812 may be formed to surround the island-shaped second adhesive layer 822. Since the second adhesive layer 822 is island-shaped, an external force may be uniformly dispersed on the non-display region even by forming only the portion of the non-display region of the display panel 200.

Referring to FIG. 9, the second adhesive layer 823 may be patterned on the non-display region of the display panel 200 at a constant interval. The first adhesive layer 813 may be positioned on the non-display region without the second adhesive layer 823 patterned. FIG. 9 shows that the second adhesive layer 823 is patterned on the non-display region of the display panel 200 at a constant interval, but aspects of the present invention are not limited thereto. Alternatively, the second adhesive layer 823 may be formed on only at corner portions of the second substrate 220 of the display panel 200.

Referring to FIG. 10, the second adhesive layer 824 may be formed on the non-display region corresponding to a long side of the second substrate 220 of the display panel 200. In an exemplary embodiment, the second adhesive layer 824 may be patterned in a shape of two vertically parallel lines (It)) so as to correspond to both long sides of the second substrate 220. The two vertical line patterns of the second adhesive layer 824 corresponding to the long sides of the second substrate 220 may be parallel to each other. In one embodiment, the first adhesive layer 814 may be formed at a central portion of the second substrate 220 and both short sides of the second substrate 220. In an exemplary embodiment, the long sides and short sides may be switched.

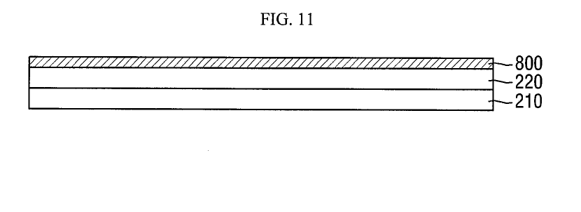

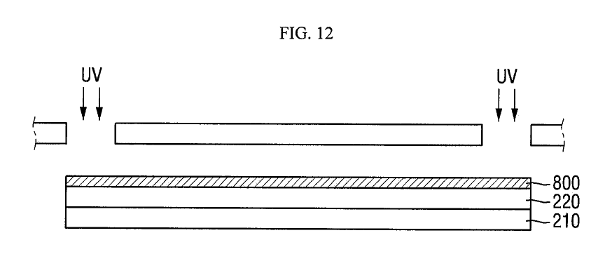

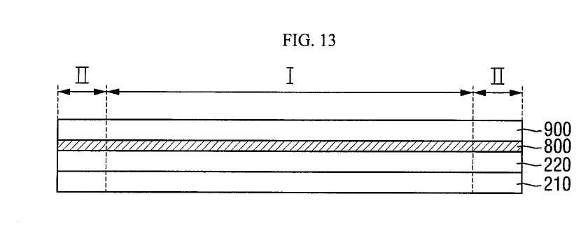

FIGS. 11 to 13 are cross-sectional views illustrating a method for manufacturing a display device according to an embodiment of the present invention. In FIGS. 11 to 13, for the sake of convenient explanation, substantially the same elements as those shown in FIGS. 1 to 3 are denoted by the same reference numerals, and repeated descriptions thereof will be omitted.

Referring to FIGS. 11 to 13, the method for manufacturing a display device according to an embodiment of the present invention includes applying an adhesive layer 800 including a photocurable material on a display panel 200, differentially irradiating light into the display panel 200, and attaching a window 900 onto the adhesive layer 800. As described above, the photocurable material may be a UV curable material.

In an exemplary embodiment, the differentially irradiating of the light into the display panel 200 may include irradiating light only into the non-display region. Therefore, if only the adhesive layer 800 located on the non-display region is cured, a modulus of elasticity of the adhesive layer 800 located on the non-display region may be greater than that of the adhesive layer 800 located on the display region.

In another exemplary embodiment, in the differentially irradiating, the light is irradiated into both of the display region and the non-display region of the display panel 200. Alternatively, a filter for reducing light energy may be inserted between the light source and the display region. In addition, the differentially irradiating comprises irradiating light into the display panel 200 in an amount gradually increasing from inside to outside of the display panel 200. In addition, the light may be differentially irradiated into the display panel 200 by arranging a plurality of light sources emitting light with different energies on the same plane of the display panel 200 or arranging a plurality of light sources emitting light with the same energy to be spaced different intervals apart from the display panel 200.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A display device comprising:
a display panel including a display region and a non-display region;
a window located on one surface of the display panel; and
an adhesive layer located between the display panel and the window,
wherein a modulus of elasticity of the adhesive layer located on the non-display region is greater than a module of elasticity of the adhesive layer located on the display region.

2. The display device of claim 1, wherein the adhesive layer comprises at least one of an optically clear adhesive and a pressure sensitive adhesive.

3. The display device of claim 2, wherein the pressure sensitive adhesive is transparent.

4. The display device of claim 1, wherein the modulus of elasticity of the adhesive layer gradually increases from a center to a periphery of the display panel.

5. The display device of claim 1, wherein the modulus of elasticity of the adhesive layer is constant throughout the display region.

6. The display device of claim 1, wherein the window is bent on the non-display region and contacts the display panel.

7. The display device of claim 1, further comprising a mold frame located on another surface of the display panel, wherein the window is bent on the non-display region and contacts the mold frame.

8. The display device of claim 7, wherein the window contacts a side surface of the display panel.

9. A display device comprising:
a display panel including a display region and a non-display region;
a window located on one surface of the display panel; and
a first adhesive layer and a second adhesive layer located between the display panel and the window,
wherein the second adhesive layer is located on at least a portion of the non-display region, and wherein a modulus of elasticity of the second adhesive layer is greater than a modulus of elasticity of the first adhesive layer.

10. The display device of claim 9, wherein the first adhesive layer and the second adhesive layer comprise different optically clear adhesives.

11. The display device of claim 9, wherein the modulus of elasticity of the adhesive layer gradually increases from a center to a periphery of the display panel.

12. The display device of claim 9, wherein at least a portion of the first adhesive layer is located on the display region, and wherein the modulus of elasticity of the adhesive layer is constant throughout the display region.

13. The display device of claim 9, wherein the first adhesive layer and the second adhesive layer are positioned on the same plane.

14. The display device of claim 9, wherein at least a portion of the first adhesive layer overlaps the second adhesive layer.

15. A display device comprising:
a display panel including a display region and a non-display region;
a window located on one surface of the display panel; and
an adhesive layer located between the display panel and the window,
wherein the adhesive layer located on the non-display region comprises a photocurable material.

16. The display device of claim 15, wherein an amount of the photocurable material gradually increases from a center to a periphery of the display panel.

17. The display device of claim 15, wherein the adhesive layer located on the display region includes the photocurable material, and an amount of the photocurable material located on the non-display region is larger than an amount of the photocurable material located on the display region.

18. A method for manufacturing a display device, the method comprising:
applying an adhesive layer including a photocurable material on a display panel;
differentially irradiating light into the display panel; and
attaching a window onto the adhesive layer.

19. The method of claim 18, wherein the display panel includes a display region and a non-display region, and wherein the differentially irradiating of the light into the display panel comprises irradiating light only into the non-display region.

20. The method of claim 18, wherein the differentially irradiating of the light into the display panel comprises irradiating light in an amount gradually increasing from a center to a periphery of the display panel.
